(19) United States
(12) Patent Application Publication
(10) Pub. No.: US 2013/0291941 A1
(43) Pub. Date: Nov. 7, 2013

(54) Solid-State Dye-Sensitized Solar Cell Using Sodium or Potassium Ionic Dopant

(71) Applicants: Sean Andrew Vail, Vancouver, WA (US); Wei Pan, Vancouver, WA (US); Gary D. Foley, Portland, OR (US); Jong-Jan Lee, Camas, WA (US)

(72) Inventors: Sean Andrew Vail, Vancouver, WA (US); Wei Pan, Vancouver, WA (US); Gary D. Foley, Portland, OR (US); Jong-Jan Lee, Camas, WA (US)

(21) Appl. No.: 13/461,674

(22) Filed: May 1, 2012

(51) Int. Cl. H01L 31/0256; H01L 31/0264; H01L 31/0376; B82Y 30/00

(52) U.S. Cl. 136/258; 136/263; 977/774; 977/948; 977/734; 977/762; 977/773; 977/811

(57) ABSTRACT

A solid-state hole transport composite material (ssHTM) is provided made from a p-type organic semiconductor and a dopant material serving as a source for either sodium (Na+) or potassium (K+) ions. The p-type organic semiconductor may be molecular (a collection of discrete molecules, that are either chemically identical or different), oligomeric, polymeric materials, or combinations thereof. In one aspect, the p-type organic semiconductor is 2,2′,7,7′-tetrakis(N,N-di-p-methoxyphenylamine)-9,9′-spirobifluorene (Spiro-OMeTAD). The dopant material is an inorganic or organic material salt. A solid-state dye-sensitized solar cell (ssDSC) with the above-described ssHTM, is also provided.

### BACKGROUND OF THE INVENTION

1. Field of the Invention

This invention generally relates to photovoltaic solar cells and, more particularly, to a solid-state hole transport composite material with a sodium or potassium ionic dopant.

2. Description of the Related Art

The dye-sensitized solar cell (DSC) represents both a promising and cost-effective alternative to expensive, thin-film photovoltaic technologies. In general, a conventional DSC device is composed of a porous semiconducting metal oxide, a dye (photosensitizer) that harvests incident light, and a liquid electrolyte for transport of positive charges (holes) from the photoexcited dye. Although appreciable power conversion efficiencies (PCEs) have been achieved using molecular photosensitizers in a conventional DSC configuration, the quest for all solid-state devices has fostered the development of solid-state dye-sensitized solar cells (ssDSCs) through which the liquid electrolyte is replaced by a solid hole-transport material (HTM). Overall, ssDSCs offer both practical and technological advantages compared to conventional DSCs, for which long-term stability and large-scale deployment are hindered by potential leakage issues associated with the volatile and corrosive nature of the electrolyte.

FIG. 1 is a schematic diagram depicting electronic processes and major loss mechanisms in a solid-state dye-sensitized solar cell (prior art). The absorption of light (photosensitizer) is followed by electron injection from the photoexcited state of the dye (D*) into the TiO₂ conduction band [1]. Subsequently, hole transfer proceeds from the oxidized dye (D+) to the HTM, after which holes are transported to a metallic counter electrode via charge “hopping” mechanisms along the HTM [2]. Following electron injection from the photoexcited dye, competition in terms of “recapture” of injected electrons (from TiO₂) by the oxidized dye (recombination) may occur [3]. Finally, additional recombination events involving electrons in the TiO₂ and holes in the HTM may proceed [4]. Strategies towards high performance ssDSC devices are focused on maximizing the efficiency of processes [1] and [2] while, at the same time, minimizing the negative impact from [3] and [4].

An ssDSC device can be fabricated using metal oxide nanoparticles with attached dye as the absorber layer, see FIG. 3A. Briefly, an appropriate blocking layer is deposited on top of a transparent conducting oxide (TCO) layer to prevent ohmic contact between the HTM and TCO. Next, a metal oxide layer (in the form of nanoparticles, nanotubes, nanowires, etc., for example) is deposited on top of the blocking layer. Subsequent to deposition, the metal oxide substrate is treated with a photosensitizer (dye) to afford a monolayer of absorber material along the surface of the metal oxide. Next, an HTM is applied to the metal oxide/dye. Finally, a metal layer (Ag or Au) is deposited on top of the HTM to complete the device.

FIG. 2 is a diagram depicting the molecular structure of 2,2′,7,7′-tetrakis(N,N-di-p-methoxyphenylamine)-9,9′-spirobifluorene (Spiro-OMeTAD) (prior art). Perhaps the most challenging aspect of ssDSC development is the preparation and optimization of the HTM matrix formulation and deposition processes, while the fabrication of the metal oxide substrate and photosensitization strategies can be directly transferred from the current DSC technology. Although 2,2′,7,7′-tetrakis(N,N-di-p-methoxyphenylamine)-9,9′-spirobifluorene (Spiro-OMeTAD) has been the preferred solid-state hole transport material (ssHTM) for ssDSC, the development of suitable alternatives represent active areas of interest.

Overall, the low intrinsic conductivity of pristine Spiro-OMeTAD films imposes challenges towards the realization of highly efficient ssDSCs. In general, the low conductivity for organic HTMs (versus inorganic) may be rationalized, at least in part, by higher degrees of disorder which afford a broad distribution of traps states throughout the HTM network. In order to compensate for the low conductivity of pure Spiro-OMeTAD films, a lithium ion (Li+) source [such as lithium bis(trifluoromethylsulfonyl)imide or LiTFSI, for example] is routinely incorporated into the HTM formulation. The necessity for the presence of Li+ in the Spiro-OMeTAD matrix was initially demonstrated by Bach et al., for which an ssDSC containing “lithium-doped” Spiro-OMeTAD demonstrated an overall efficiency of 0.74% (with accessory dopant) versus 0.04% for a control device (no additives), Bach, U.; Lupo, D.; Comte, P.; Moser, J.; Weissörtel, F.; Salbeck, J.; Spreitzer, H.; Grätzel, M. Nature 1998, 395, 583-585.

Since this pioneering work, subsequent publications have verified the critical role of Li+ in ssDSCs based upon Spiro-OMeTAD towards achieving higher PCEs. Krüger et al. demonstrated an ssDSC efficiency of 2.56% using Spiro-OMeTAD containing LiTFSI and 4-tert-butyl pyridine (TBP), whereby an appreciable open-circuit voltage (V_{oc}) from suppression of interfacial charge carrier recombination was confirmed by nanosecond laser spectroscopy, Krüger, J.; Plass, R.; Cevey, L.; Piccirelli, M.; Gratzel, M.; Bach, U. Applied Physics Letters 2001, 79, 2085-2087. Snaith et al. showed that the addition of a redox inactive ionic dopant (Li+ in the form of LiTFSI) afforded up to a 100-fold increase in conductivity and up to one order of magnitude enhancement in hole mobility for the Spiro-OMeTAD composite, Snaith, H. J.; Grätzel, M. Applied Physics Letters 2006, 89, 262114-1-262114-3. Studies reported both previously and subsequently to the aforementioned support the notion that appropriate doping with Li+ is critical for achieving high efficiencies in ssDSCs using Spiro-OMeTAD as HTM, Haque, S. A.; Tachibana, Y.; Willis, R. L.; Moser, J. E.; Gratzel, M.; Klug, D. R.; Durrant, J. R. Journal of Physical Chemistry B 2000, 104, 538-547, and Fabreget-Santiago, F.; Bisquert, J.; Chevey, L.; Chen, P.; Wang, M.; Zakeerudiin, S. M.; Grätzel, M. Journal of the American Chemical Society 2009, 131, 558-562.

Although a detailed treatment of the underlying mechanism(s) through which the observed enhancements are realized is not explicitly presented herein, it appears likely that Li+ does not provide access to higher oxidation states of Spiro-OMeTAD. In addition, it is possible that the localized (positive) charges populated along the TiO₂ surface may facilitate electron injection from the attached photosensitizer following irradiation as well as provide conductive channels throughout the HTM network. However, the fact that it has been shown internally that increased Li+ concentrations in the Spiro-OMeTAD matrix negatively impacts the V_{oc} of the device when used in combination with a high molar extinction coefficient photosensitizer suggests that Li+ is a potential determining species for TiO₂, whereby increased short-circuit photocurrent density (J_{sc}) is enhanced at the expense of open circuit voltage (V_{oc}).

To further compensate for the poor conductivity of pristine Spiro-OMeTAD films, the generation of additional charge carriers via chemical doping methods has been employed. Through appropriate strategies, the conductivity through the HTM matrix can be increased, thereby decreasing the frequency for recombination events that negatively impact V_{oc}. A large variety of materials have been described for p-doping applications including strongly electron-accepting organic materials, transition metal oxides, metal organic complexes and redox active salts. For ssDSC, Bach et al. employed tris(p-bromophenyl) ammoniumyl hexachloroantimonate [N(p-C₆H₄Br)₃SbC₆] as dopant in ssDSC with Spiro-OMeTAD as HTM. Recently, Burschka et al. described the incorporation of a tris[2-(1H-pyrazol-1-yl)pyridine]cobalt(III) complex (designated FK102) as dopant in ssDSC with an organic dye as photosensitizer (designated Y123) and Spiro-OMeTAD as HTM, Burschka, J.; Dualeh, A.; Kessler, F.; Baranoff, E.; Cevey-Ha, N-L.; Yi, C.; Nazeeruddin, M. K.; Grätzel, M. J. Am. Chem. Soc. 2011, 133, 18042-18045. Overall, FK102 was determined to have a redox potential of −1.06 V (NHE), thereby providing approximately 350 mV driving force for the one electron oxidation of Spiro-OMeTAD. In spite of these successes, the extent (or scope) to which p-doping in ssDSC is beneficial remains controversial since the modest increase in conductivity (due to dopant) is often counterbalanced by an increase in charge recombination.

It would be advantageous if organic p-type (hole transport) materials such as Spiro-OMeTAD could be appropriately doped to improve J_{sc}, V_{oc}, and series resistance (Rₛ), towards achieving higher overall PCEs.

### SUMMARY OF THE INVENTION

Disclosed herein is a strategy for redox inactive ionic doping of hole transport material (HTM) matrices for improved solid-state dye-sensitized solar cell (ssDSC) performance. As a proof of concept, a sodium salt (sodium bis(trifluoromethanesulfonyl)imide or NaTFSI) was employed in combination with Spiro-OMeTAD as a representative HTM. Initial prototype ssDSC devices demonstrate enhanced photovoltaic performance relative to control devices (using LiTFSI). This strategy provides a new paradigm for the fabrication of ssDSCs based upon solid-state hole transport materials such as Spiro-OMeTAD (or similar materials).

Accordingly, an ssHTM is provided made from a p-type organic semiconductor and a dopant material serving as a source for either sodium (Na+) or potassium (K+) ions. The p-type organic semiconductor may be molecular (a collection of discrete molecules, that are either chemically identical or different), oligomeric, polymeric materials, or combinations thereof. In one aspect, the p-type organic semiconductor is 2,2′,7,7′-tetrakis(N,N-di-p-methoxyphenylamine)-9,9′-spirobifluorene (Spiro-OMeTAD). The dopant material is an inorganic or organic material salt.

Additional details of the above-described HTM, and an ssDSC with the above-described ssHTM, is provided below.

### BRIEF DESCRIPTION OF THE DRAWINGS

FIG. 1 is a schematic diagram depicting electronic processes and major loss mechanisms in a solid-state dye-sensitized solar cell (prior art).

FIG. 2 is a diagram depicting the molecular structure of 2,2′,7,7′-tetrakis(N,N-di-p-methoxyphenylamine)-9,9′-spirobifluorene (Spiro-OMeTAD) (prior art).

FIGS. 3A and 3B are partial cross-sectional views of an ssDSC with a solid-state hole transport material (ssHTM).

FIG. 4 is a schematic diagram depicting the ssHTM of FIG. 3A or 3B.

FIG. 5 is a schematic depicting the molecular structure of sodium bis(trifluoromethanesulfonyl)imide (NaTFSI).

FIG. 6 is a graph depicting external quantum efficiency (EQE) spectra for ssDSCs using Spiro-OMeTAD containing 15 mol % LiTFSI (Device SU1402) or NaTFSI at concentrations of either 15.1 mol % (Devices SU1708 and SU1710) or 30.2 mol % (Device SU1709) from 300-800 nm.

FIG. 7 is a graph depicting IV curves for ssDSCs using Spiro-OMeTAD containing NaTFSI at concentrations of either 15.1 mol % (Devices SU1708 and SU1710) or 30.2 mol % (Device SU1709).

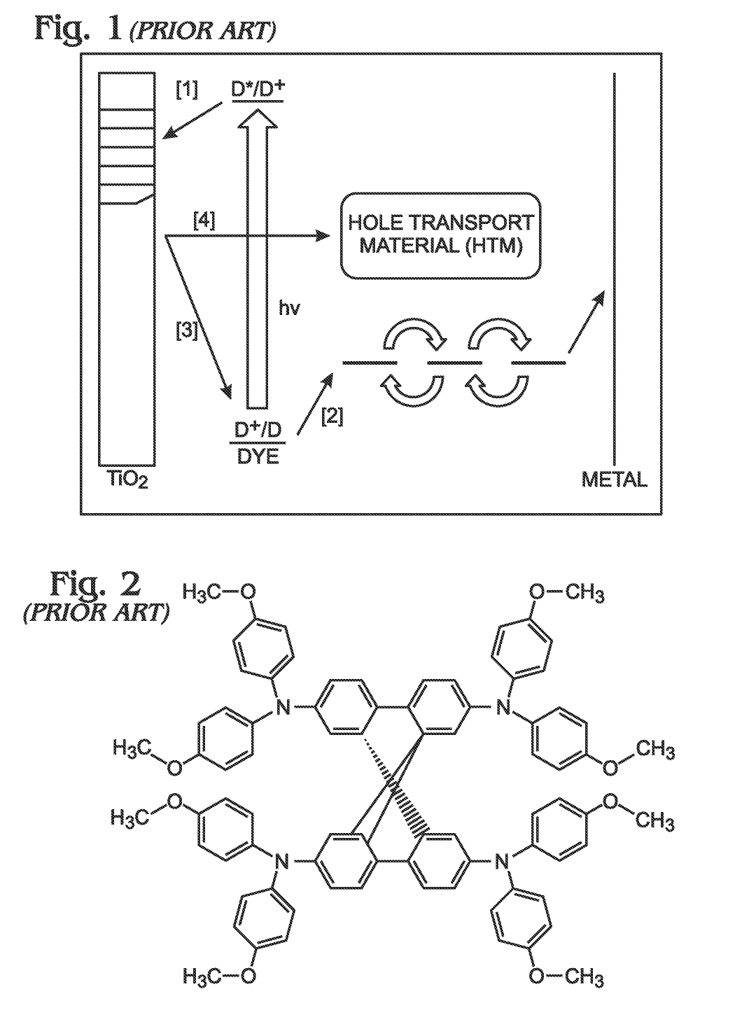

### DETAILED DESCRIPTION

FIGS. 3A and 3B are partial cross-sectional views of an ssDSC with a solid-state hole transport material (ssHTM). The ssDSC 300 comprises a transparent platform 302, typically made from glass or flexible material. A transparent conducting oxide (TCO) 304 overlies the transparent platform 302. Some examples of a TCO material include fluorine doped tin oxide (FTO), doped zinc oxide (ZnO), and indium tin oxide (ITO). As shown in FIG. 3A, a blocking layer 306 overlies the TCO 304. The blocking layer 306 is electrically conductive, but prevents ohmic contact between the TCO and an ssHTM layer. A dye-sensitized n-type semiconductor 308 overlies the blocking layer 306. The ssHTM layer 310 overlies the dye-sensitized n-type semiconductor 308. A metal layer 312 overlies the ssHTM 310. For example, the metal may be Ag or Au. Alternatively, FIG. 3B depicts an ssDSC with no blocking layer.

Typically, the blocking layer consists of a thin layer of compact metal oxide. For example, the blocking layer may be a compact film of TiO₂, which is deposited by spray pyrolysis from a TiO₂ precursor. Although the compact layer is conductive, it forms a physical barrier to prevent organic HTM from contacting TCO (ohmic). Spin coating of the HTM solution might otherwise lead to penetration through the n-type semiconductor 308 (e.g. nanoparticle TiO₂) to the underlying TCO surface.

The junction formed between a p-type semiconductor material (hole transporter) 310 and the n-type semiconductor material (electron transporter) 308 constitutes a p-n heterojunction, which represents the fundamental basis of diodes and transistors including related devices such as light emitting diodes (LEDs) and photovoltaic (PV) cells. “Solid-state” simply implies that the material is a solid or quasi-solid (non liquid) under ambient conditions.

The n-type semiconductor 308 dye may be made from molecular (organic) materials, metal-organic complexes, ruthenium-pyridyl complexes, porphyrins, metalloporphyrins, phthalocyanines, metallophthalocyanines, squaraines, indolenes, coumarins, thiophene and fluorene-based materials, oligomeric, and polymeric photosensitizers, “quantum dots”, or combinations thereof. Briefly, a quantum dot is a semiconductor whose electronic characteristics are closely related to the size and shape of the individual crystal. Consequently, such materials have electronic properties intermediate between those of bulk semiconductors and those of discrete molecules.

The n-type semiconductor 308 may be an oxide made from the following: titanium (TiO₂), aluminum (Al₂O₃), tin (SnO₂), magnesium (MgO), tungsten (WO₃), niobium (Nb₂O₅), and mixed metal oxides including more than one type of metal. The n-type semiconductor 308 may take the form of nanoparticles, nanotubes, nanorods, nanowires, or combinations of the above-mentioned morphologies. In the case of a metal oxide film formed from nanoparticles, a mesoporous film with a thickness of 0.01-40 microns is preferred. It should be understood that this is not intended to be an exhaustive list of n-type semiconductor materials or forms.

The surface of the n-type material is functionalized by at least one type of photosensitizer which functions as a light harvesting moiety. The surface functionalization of the n-type semiconductor by photosensitizer moieties can achieved by a single, sequential and combined process (in the case of 2 or more photosensitizers) by contacting the n-type semiconductor material with a solution of photosensitizer(s) dissolved in an appropriate solvent. In general, the junction includes at least one p-type material (hole transporter) consisting of an organic semiconductor that is doped with Na+ and K+.

In the ssDSC device, the hole transport material directly contacts the photosensitizer materials. The most commonly employed photosensitizers in DSC technology include organic materials and metal complexes. It should be understood that the ssHTM presented herein is essentially independent of the nature of the photosensitizer material(s).

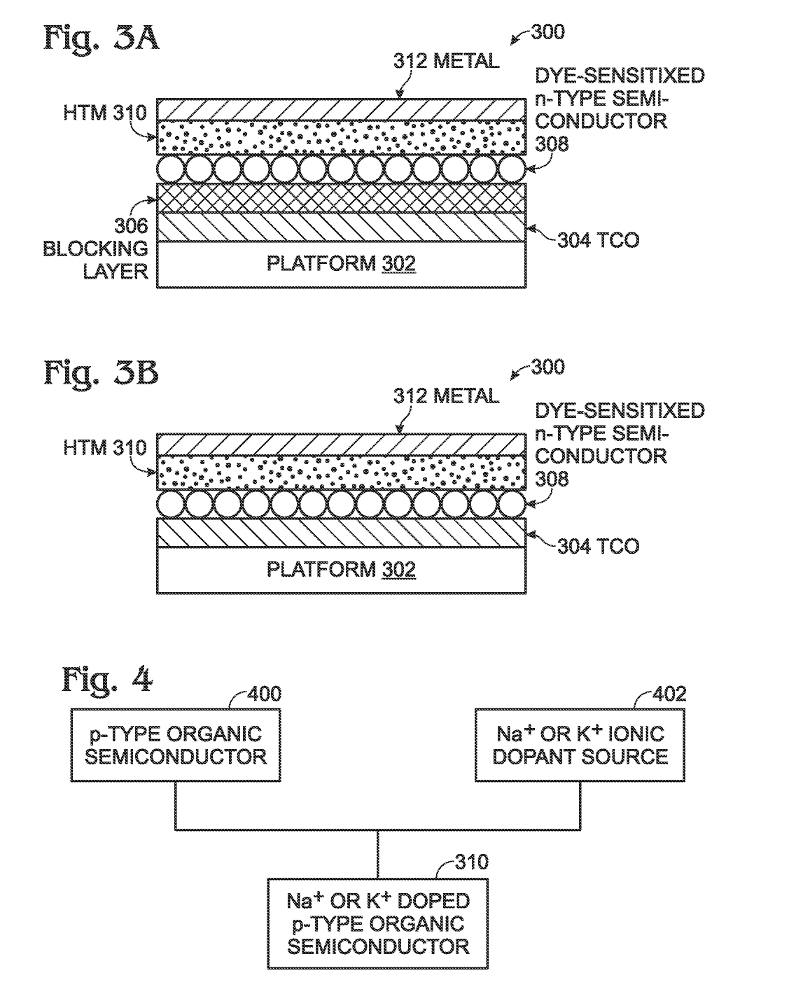

FIG. 4 is a schematic diagram depicting the ssHTM of FIG. 3A or 3B. The ssHTM 310 comprises a p-type organic semiconductor 400 and a dopant material 402 serving as a source for cations. The cation source may be either sodium (Na+) or potassium (K+) ions. In one aspect, the ssHTM dopant material 402 may be an inorganic material salt. Some examples of suitable inorganic materials include sodium or potassium salts of fluoride, bromide, chloride, iodide, azide, cyanide, arsenate, hexafluoroarsenate, chlorate, perchlorate, iodate, carbonate, bicarbonate, sulfite, sulfate, molybdate, phosphate, nitrite, nitrate, tetraborate, tetrafluoroborate, thiocyanate, hexafluorophosphate, peroxide, and combinations thereof. It should be understood that this is not intended to be an exhaustive list of inorganic material salts, and that other unnamed inorganic salts may enable the ssHTM.

Alternatively, the dopant material is an organic material salt. Some examples of organic material salts include organic carboxylates, phosphonates, sulfonates, thiolates, phenolates, alkylacetylides, acetoacetates, acetylacetonates, trifluoromethanesulfonates, amides, dialkylamides, bis(trimethylsilyl)amides, bis(trifluoromethylsilyl)amides, bis(alkylsulfonyl)imides, bis(trifluoroalkylsulfonyl)imides, and combinations thereof. In another aspect, the organic material salt 402 is bis(trifluoromethanesulfonyl)imide. It should be understood that this is not intended to be an exhaustive list of organic material salts, and that other unnamed organic salts may enable the ssHTM.

In one aspect, the ssHTM p-type organic semiconductor 400 is molecular, i.e. a collection of discrete molecules that are chemically identical or different, oligomeric, polymeric materials, or combinations thereof. In another aspect, the p-type organic semiconductor 400 is 2,2′,7,7′-tetrakis(N,N-di-p-methoxyphenylamine)-9,9′-spirobifluorene (Spiro-OMeTAD). Again, it should be understood that this is not intended to be an exhaustive list of every p-type semiconductor that may enable the ssHTM.

While the p-type organic semiconductor 400 preferably has an amorphous structure, it may alternatively have a crystalline or combination crystalline/amorphous structure. The p-type organic semiconductor 400 has a charge state of neutral, positively charged (oxidized state), or combinations thereof.

In one case, the hole-transporter exhibits a high enough HOMO to LUMO energy transition in order for photosensitizer regeneration and hole transport to be the dominant operative functions. Optionally, a more narrow HOMO to LUMO transition provides the added ability to harvest incident light followed by transfer of excited state energy to a photosensitizer attached to the surface of the n-type material. In this case, the photosensitizer transfers an electron to the n-type material and a hole to the p-type material as customary in the photoconversion process.

In general, organic HTMs have high resistance in the pristine state. As a result, the overall ssDSC performance tends to be lower in the absence of “additives” or “dopants”. In general, the HTM is dissolved in a solvent to form a solution. To this solution is added an ionic dopant, which may be separately dissolved in the same or different solvent and subsequently added to the HTM solution. Following spin-coating of the HTM solution, a more conductive matrix (film) is ultimately formed. Additional additives are conventionally included into the solution containing the HTM and ionic dopant. Although these additives do not necessarily impact the performance of the HTM, overall device performance does benefit. In some cases, these conventional additives (such as 4-tert-butylpyridine or many others) increase the overall V_{oc} of the device, although this occurs most likely through beneficial shifting of the TiO₂ band edges (n-type semiconductor). In light of this, additional additives may benefit the overall ssDSC but not directly impact the HTM properties. As opposed to redox inactive, ionic dopants (Li+ and Na+/K+ as described here), some conventional processes add redox active materials to the solution of HTM and ionic dopant. These materials change the oxidation state of the HTM (oxidize), thereby providing additional charge carriers, which increases conductivity and/or hole mobility. HTM may be utilized in either a neutral or charged state and in addition to the ionic dopant (Na+, K+), the HTM composite material may contain redox active additives and additional nonredox active dopants.

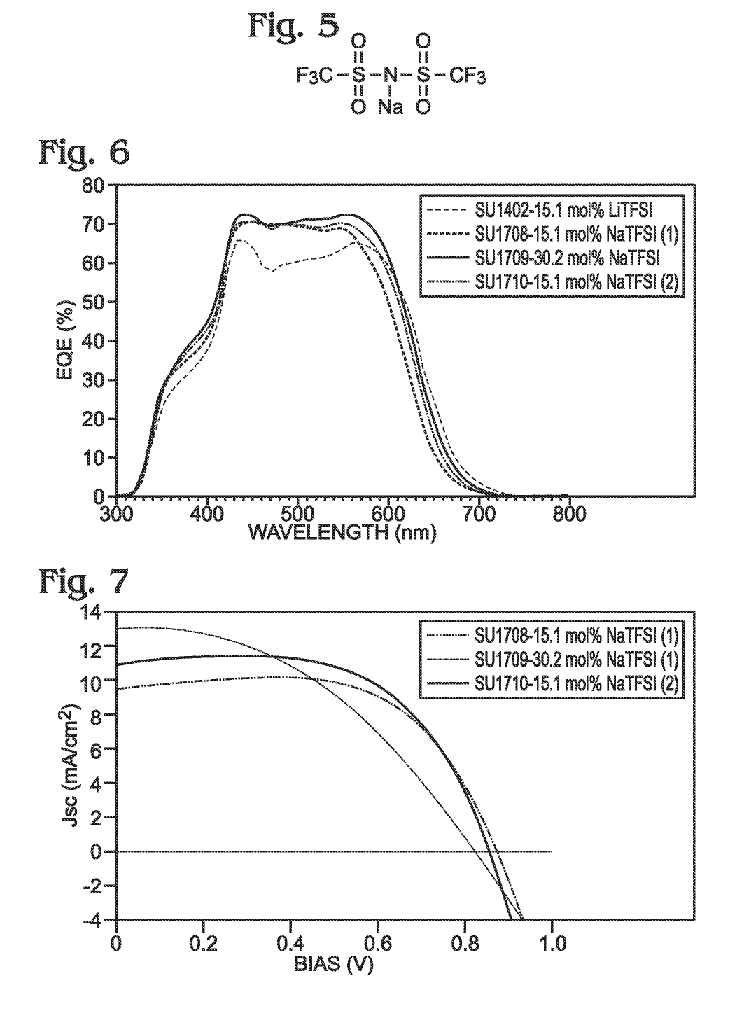

FIG. 5 is a schematic depicting the molecular structure of sodium bis(trifluoromethanesulfonyl)imide (NaTFSI). Lithium salts (LiTFSI and/or others) have conventionally demonstrated a beneficial role as additives in HTM matrices based upon Spiro-OMeTAD and have been utilized extensively as part of the “mainstream” approach for ssDSC. Although there are several avenues through which the behavior of the ionic dopant manifests itself to the benefit of individual photovoltaic parameters, the specific mechanistic details are not presented herein. Rather, an alternative ionic doping strategy is used herein whereby Li+ is replaced by Na+ or K+ while preserving most other aspects of the traditional ssDSC fabrication process(es). For these purposes, NaTFSI was judiciously chosen due to an appreciable solubility in organic solvents, as well as the fact that the TFSI− (counterion) is common to that of the lithium source (LiTFSI) in conventional Spiro-OMeTAD formulations. Furthermore, it is plausible that high degrees of charge delocalization associated with TFSI− may either induce preferential stacking of HTMs or simply function as “bridges” across trap sites, thereby improving overall conductivity throughout the HTM network.

Prototype ssDSCs Containing NaTFSI (15.1 Mol/o and 30.2 Mol %) or LiTFSI (15.1 mol %) Based on Spiro-OMeTAD

In general, an HTM formulation consisting of Spiro-OMeTAD, 4-tert-butylpyridine (TBP), NaTFSI (or LiTFSI as a control) in a mixture of chlorobenzene (CB) and acetonitrile (CH₃CN) was spin-coated onto TiO₂ nanoparticle substrates that had previously been soaked in a solution of photosensitizer (0.1 mM) dissolved in a mixture of tert-butanol and acetonitrile (1:1 by volume). Following drying, a silver electrode (200 nm thick) was deposited on top of the HTM film. The specific experimental details for the formulations are:

Spiro-OMeTAD/CB Solution:

Spiro-OMeTAD (45 mg, 0.037 mmol) was dissolved in chlorobenzene (CB, 200 μL) at 70° C. on a hot plate.

LiTFSI/CH₃CN Solution:

Lithium bis(trifluoromethylsulfonyl)imide (LiTFSI, 21.25 mg) was dissolved in acetonitrile (CH₃CN, 100 μL).

NaTFSI/CH₃CN Solution:

Sodium bis(trifluoromethylsulfonyl)imide [NaTFSI, 22.4 mg (15.1 mol %) and 44.8 mg (30.2 mol %) were dissolved in acetonitrile (CH₃CN, 100 μL).

Device SU1402 (Spiro-OMeTAD, 15.1 mol % LiTFSI):

To Spiro-OMeTAD/CB was added tert-butylpyridine (TBP, 4.4 μL), LiTFSI/CH₃CN (7.5 μL) and CH₃CN (6 μL).

Device SU1708 (Spiro-OMeTAD, 15.1 mol % NaTFSI):

To Spiro-OMeTAD/CB was added 4-tert-butylpyridine (TBP, 4.4 μL), NaTFSI/CH₃CN (7.5 μL of 15.1 mol % solution) and CH₃CN (6 μL).

Device SU1710 (Spiro-OMeTAD. 15.1 mol % NaTFSI):

To Spiro-OMeTAD/CB was added 4-tert-butylpyridine (TBP, 4.4 μL), NaTFSI/CH₃CN (7.5 μL of 15.1 mol % solution) and CH₃CN (12 μL).

Device SU1709 (Spiro-OMeTAD, 30.2 mol % NaTFSI):

To Spiro-OMeTAD/CB was added 4-tert-butylpyridine (TBP, 4.4 μL), NaTFSI/CH₃CN (7.5 μL of 30.2 mol % solution) and CH₃CN (12 μL).

ssDSC Prototype Evaluation: External Quantum Efficiency (EQE %)

FIG. 6 is a graph depicting external quantum efficiency (EQE) spectra for ssDSCs using Spiro-OMeTAD containing 15 mol % LiTFSI (Device SU1402) or NaTFSI at concentrations of either 15.1 mol % (Devices SU1708 and SU1710) or 30.2 mol % (Device SU1709) from 300-800 nm. The y-axis: external quantum efficiency (EQE) in %; x-axis: Wavelength in nanometers (nm). In general, there exists a trend towards higher EQE % (and corresponding short-circuit current (J_{sc})) for all devices containing NaTFSI (15.1 and 30.2 mol %) as ionic dopant in the Spiro-1-OMeTAD HTM relative to LiTFSI (15.1 mol %), with ratios of all other functional components in the formulation being identical.

ssDSC Prototype Evaluation: IV Characteristics

FIG. 7 is a graph depicting IV curves for ssDSCs using Spiro-OMeTAD containing NaTFSI at concentrations of either 15.1 mol % (Devices SU1708 and SU1710) or 30.2 mol % (Device SU1709). Measurements were performed using an aperture size of 0.25 cm² [y-axis: J_{sc} (mA/cm²); x-axis: voltage (V). A summary of the photovoltaic characteristics is provided in Table 1.

TABLE 1
Summary of photovoltaic characteristics for ssDSC devices
1402 and 1708-1710 from solar simulator measurements: concentration
of LiTFSI and NaTFSI (mol %), short-circuit current density (J_{sc}),
open-circuit voltage (V_{oc}), fill factor (FF), efficiency
(η) and series resistance (Rs).

| | | | | | | | Rₛ^{b} |
|---|---|---|---|---|---|---|---|
| Device | LiTFSI^{a} | NaTFSI^{a} | J_{sc}^{b} | V_{oc}^{b} | | η^{b} | (ohm- |
| ID | (mol %) | (mol %) | (mA/cm²) | (mV) | FF^{b} | (%) | cm²) |
| SU1402 | 15.1 | 0 | 10 | 820 | 45.9 | 3.8 | 24.2 |
| SU1708 | 0 | 15.1 | 9.6 | 874 | 65.9 | 5.5 | 16.4 |
| SU1709 | 0 | 30.2 | 13.1 | 820 | 43.0 | 4.6 | 28.0 |
| SU1710 | 0 | 15.1 | 11.0 | 855 | 62.5 | 5.9 | 15.0 |

^{a}mol % based on Spiro-OMeTAD
^{b}aperture size = 0.25 cm²

As can be seen from Table 1, higher overall efficiencies are obtained for ssDSCs containing HTM doped with NaTFSI (SU1708-1710) relative to control device with LiTFSI (SU1402). In general, the higher power conversion efficiencies for NaTFSI containing ssDSCs (versus LiTFSI) manifest themselves in terms of greater J_{sc} (SU1709 and SU1710), higher V_{oc} (SU1708 and SU1710), better FF (SU1708 and SU1710) and lower Rₛ (SU1708 and SU1710).

In summary, described herein is a technology for improving the power conversion efficiencies of ssDSC prototypes using Spiro-OMeTAD as HTM with Na+ or K+ as an ionic dopant alternative to Li+. It is likely that the measured results can be attributed to both (1) the preservation of conductivity through, and hole mobility for, the HTM due to the presence of Na+ and increased V_{oc} arising from decreased shifting of TiO₂ band potentials to more positive values (versus Li+). This work represents the first demonstration of successful HTM doping with Na+ in ssDSC, and similar results are likely for K+ doping.

An ssDSC and an ssHTM using K or Na cation dopants have been provided. Examples of particular materials have been presented to illustrate the invention. However, the invention is not limited to merely these examples. Other variations and embodiments of the invention will occur to those skilled in the art.

We claim:

1. A solid-state hole transport composite material (ssHTM) comprising:
a p-type organic semiconductor; and,
a dopant material serving as a source for cations selected from a group consisting of sodium (Na+) and potassium (K+) ions.

2. The ssHTM of claim 1 wherein the dopant material is an inorganic material salt.

3. The ssHTM of claim 2 wherein the inorganic material salt is selected from a group consisting of fluoride, bromide, chloride, iodide, azide, cyanide, arsenate, hexafluoroarsenate, chlorate, perchlorate, iodate, carbonate, bicarbonate, sulfite, sulfate, molybdate, phosphate, nitrite, nitrate, tetraborate, tetrafluoroborate, thiocyanate, hexafluorophosphate, peroxide, and combinations thereof.

4. The ssHTM of claim 1 wherein the dopant material is an organic material salt.

5. The ssHTM of claim 4 wherein the organic material salt is selected from a group consisting of carboxylates, phosphonates, sulfonates, thiolates, phenolates, alkylacetylides, acetoacetates, acetylacetonates, trifluoromethanesulfonates, amides, dialkylamides, bis(trimethylsilyl)amides, bis(trifluoromethylsilyl)amides, bis(alkylsulfonyl)imides, bis(trifluoroalkylsulfonyl)imides, and combinations thereof.

6. The ssHTM of claim 4 wherein the organic material salt is bis(trifluoromethanesulfonyl)imide.

7. The ssHTM of claim 1 wherein the p-type organic semiconductor is selected from a group consisting of molecular (collection of discrete molecules, chemically identical or different), oligomeric, polymeric materials, and combinations thereof.

8. The ssHTM of claim 7 wherein the p-type organic semiconductor is 2,2′,7,7′-tetrakis(N,N-di-p-methoxyphenylamine)-9,9′-spirobifluorene (Spiro-OMeTAD).

9. The ssHTM of claim 1 wherein the p-type organic semiconductor has an amorphous structure.

10. The ssHTM of claim 1 wherein the p-type organic semiconductor has a charge state selected from a group consisting of neutral, positively charged (oxidized state), and combinations thereof.

11. A solid-state dye-sensitized solar cell (ssDSC) with a solid-state hole transport material (ssHTM), the ssDSC comprising:
a transparent platform;
a transparent conducting oxide (TCO) overlying the transparent platform;
a dye-sensitized n-type semiconductor overlying the TCO;
a ssHTM overlying the dye-sensitized n-type semiconductor comprising:
a p-type organic semiconductor;
a dopant material serving as a source for cations selected from a group consisting of sodium (Na+) and potassium (K+) ions; and,
a metal layer overlying the ssHTM.

12. The ssDSC of claim 11 wherein the ssHTM dopant material is an inorganic material salt selected from a group consisting of fluoride, bromide, chloride, iodide, azide, cyanide, arsenate, hexafluoroarsenate, chlorate, perchlorate, iodate, carbonate, bicarbonate, sulfite, sulfate, molybdate, phosphate, nitrite, nitrate, tetraborate, tetrafluoroborate, thiocyanate, hexafluorophosphate, peroxide, and combinations thereof.

13. The ssDSC of claim 11 wherein the dopant material is an organic material salt selected from a group consisting of organic carboxylates, phosphonates, sulfonates, thiolates, phenolates, alkylacetylides, acetoacetates, acetylacetonates, trifluoromethanesulfonates, amides, dialkylamides, bis(trimethylsilyl)amides, bis(trifluoromethylsilyl)amides, bis(alkylsulfonyl)imides, bis(trifluoroalkylsulfonyl)imides, and combinations thereof.

14. The ssDSC of claim 11 wherein the organic material salt is bis(trifluoromethanesulfonyl)imide.

15. The ssDSC of claim 11 wherein the ssHTM p-type organic semiconductor is selected from a group consisting of molecular (collection of discrete molecules, chemically identical or different), oligomeric, polymeric materials, and combinations thereof.

16. The ssDSC of claim 15 wherein the p-type organic semiconductor is 2,2′,7,7′-tetrakis(N,N-di-p-methoxyphenylamine)-9,9′-spirobifluorene (Spiro-OMeTAD).

17. The ssDSC of claim 11 wherein the n-type semiconductor dye is selected from a group consisting of molecular (organic) materials, metal-organic complexes, ruthenium-pyridyl complexes, porphyrins, metalloporphyrins, phthalocyanines, metallophthalocyanines, squaraines, indolenes, coumarins, thiophene and fluorene-based materials, oligomeric, and polymeric photosensitizers, “quantum dots”, and combinations thereof.

18. The ssDSC of claim 11 wherein the n-type semiconductor is a metal oxide selected from a group consisting of titanium (TiO₂), aluminum (Al₂O₃), tin (SnO₂), magnesium (MgO), tungsten (WO₃), niobium (Nb₂O₅), and mixed metal oxides including more than one type of metal.

19. The ssDSC of claim 18 wherein the n-type semiconductor has a form selected from a group consisting of nanoparticles, nanotubes, nanorods, nanowires, and combinations of the above-mentioned morphologies.

20. The ssDSC of claim 11 wherein the p-type organic semiconductor has an amorphous structure.

21. The ssDSC of claim 11 wherein the p-type organic semiconductor has a charge state selected from a group consisting of neutral, positively charged (oxidized state), and combinations thereof.

22. The ssDSC of claim 11 further comprising:
a blocking layer interposed between the TCO and the dye-sensitized n-type semiconductor.
